(19) United States
(12) Patent Application Publication
(10) Pub. No.: US 2025/0181786 A1
(43) Pub. Date: Jun. 5, 2025

(54) INVERSE MODELLING BASED APPROACH FOR LAND COVERING MAPPING

(71) Applicant: Regents of the University of Minnesota, Minneapolis, MN (US)

(72) Inventors: Praveen Ravirathinam, Minneapolis, MN (US); Rahul Ghosh, Minneapolis, MN (US); Ankush Khandelwal, Minneapolis, MN (US); Vipin Kumar, Minneapolis, MN (US); David Mulla, Minneapolis, MN (US)

(21) Appl. No.: 18/958,619

(22) Filed: Nov. 25, 2024

Related U.S. Application Data
(60) Provisional application No. 63/605,220, filed on Dec. 1, 2023.

(51) Int. Cl. G06F 30/13; G01W 1/10; G06F 30/27

(52) U.S. Cl. CPC G06F 30/13; G01W 1/10; G06F 30/27

(57) ABSTRACT

A method includes receiving spatiotemporal spectral information for an area, wherein the area is divided into sub-areas and the spatiotemporal spectral information comprises spectral values for each sub-area. Spatiotemporal weather information is also received for the area. Spatiotemporal hidden states are formed from the spatiotemporal spectral information and the spatiotemporal weather information. The spatiotemporal hidden states are applied to a neural network to obtain a probability of a land cover type for each sub-area of the area.

### CROSS-REFERENCE TO RELATED APPLICATION

The present application is based on and claims the benefit of U.S. provisional patent application Ser. No. 63/605,220, filed Dec. 1, 2023, the content of which is hereby incorporated by reference in its entirety.

This invention was made with government support under IIS-1838159 and OAC-1934721 awarded by the National Science Foundation. The government has certain rights in the invention.

### BACKGROUND

Land cover prediction systems are complex technological systems that utilize satellites to capture multi-spectral images of land areas that are then used to predict what type of cover, such as trees, crops, urban areas and sand, are present in the images.

The discussion above is merely provided for general background information and is not intended to be used as an aid in determining the scope of the claimed subject matter. The claimed subject matter is not limited to implementations that solve any or all disadvantages noted in the background.

### SUMMARY

A method includes receiving spatiotemporal spectral information for an area, wherein the area is divided into sub-areas and the spatiotemporal spectral information comprises spectral values for each sub-area. Spatiotemporal weather information is also received for the area. Spatiotemporal hidden states are formed from the spatiotemporal spectral information and the spatiotemporal weather information. The spatiotemporal hidden states are applied to a neural network to obtain a land cover type for each sub-area of the area.

In accordance with a further embodiment, a system for predicting land cover types for sub-areas in an area includes an encoder, an attention neural network, a decoder and a selector. The encoder receives a time series of spectral values for each sub-area in the area and a time series of weather values for the sub-areas in the area. The encoder uses the time series of spectral values to determine a time series of hidden spectral states and uses the time series of weather values to determine a time series of hidden weather states. The encoder combines the time series of hidden spectral states and the time series of hidden weather states to form a time series of combined hidden states. The attention neural network aggregates the combined hidden states to form final embedding hidden states while providing different levels of attention to different respective time points in the time series of combined hidden states. The decoder provides probabilities for each of a plurality of land cover types for each sub-area based on the final embedding states. The selector uses the probabilities for each of the plurality of land cover types for each sub-area to select a land cover type for each sub-area.

In accordance with a still further embodiment, a method includes generating hidden states from a combination of spectral data and weather data for an area comprising a plurality of sub-areas and applying the hidden states to an attention neural network to form an embedding. The embedding is applied to a decoder to generate probabilities for a plurality of possible land covers for each sub-area. The probabilities are used to identify a land cover for each sub-area.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 provides a diagram showing a conceptual representation of predicting land cover types.

FIG. 2 provides a block diagram of a system for predicting land cover types in accordance with one embodiment.

FIG. 3 provides a top-down view of geographic locations used for training and testing of the various embodiments.

FIG. 4 is a map of predicted land cover types with various temporal amounts of data for a prior art system and an embodiment.

FIG. 5 is a map of predicted land cover types with various temporal amounts of data for a prior art system and an embodiment.

FIG. 6A provides graphs of attention weights generated by the prior art and an embodiment for corn.

FIG. 6B provides graphs of attention weights generated by the prior art and an embodiment for almonds.

FIG. 6C provides graphs of attention weights generated by the prior art and an embodiment for cotton.

FIG. 6D provides graphs of attention weights generated by the prior art and an embodiment for grapes.

FIG. 7 is a block diagram of a computing device that can be used in the various embodiments.

### DETAILED DESCRIPTION

A crop map indicates where different crops are being grown in a region. Accurate and timely crop maps can facilitate land use planning, yield estimation, pest management, and the evaluation of sustainable management practices and conservation efforts. The USDA generates crop maps by surveying farmers to determine what crops were grown on the farmers' fields. However, responses to the surveys are incomplete and tend to include errors. Further, surveying the farmers and generating the crop maps from the surveys requires a great deal of time and effort. As a result, the resulting crop maps are inaccurate and are not issued as early as desired.

To overcome these issues, technological systems have been created that generate crop maps from satellite images. Because these images are taken from space, each pixel of an image covers a substantial area on earth. These systems attempt to identify what is growing in an area covered by a pixel using spectral information received for that pixel. This limited amount of information makes it difficult for both people and computers to determine what is growing in an area covered by a pixel. For example, many crops provide the same spectral information during parts of the growing season. As such, both people and computers make mistakes when predicting what crops are being grown based on a satellite image. In addition, these systems must overcome variations in the images caused by variable lighting conditions and varying cloud cover. Thus, crop identification from satellite images is ongoing technological challenge.

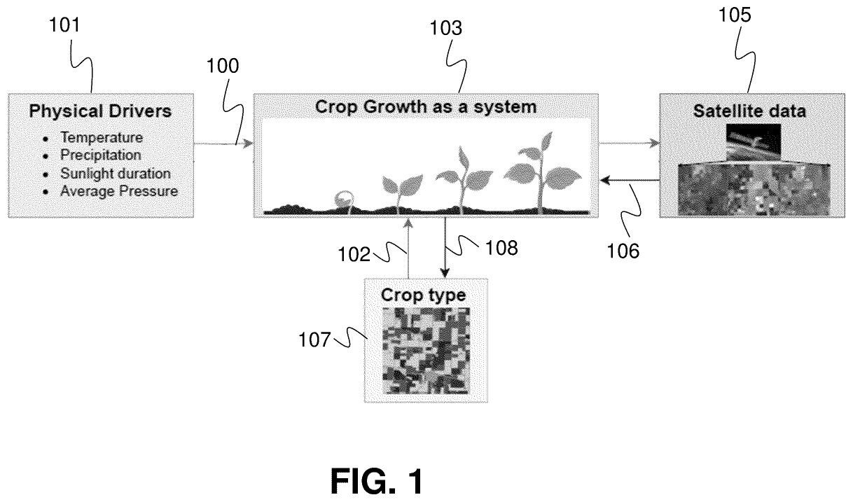

Crop growth can be viewed as a complex system involving the interplay of physical parameters such as weather conditions, soil characteristics, and management practices. These factors interact with the specific crop type at a given location, influencing the crop's growth and development. This dynamic process can be observed and analyzed through remote sensing techniques, e.g., using multi-spectral optical sensors onboard satellites. FIG. 1 provides a visual representation to understand this system better. Arrows 100 and 102 illustrate a forward process, where physical drivers 101 such as weather, soil, and management practices (arrow 100) and crop type 107 (arrow 102) impact crop growth 103. Arrow 104 indicates a forward process where crop growth 103 determines an image 105 captured by the satellites. Arrows 106 and 108 represent the flow of traditional crop mapping approaches that take satellite imagery 105 as input and generate crop labels 107 as output. Clearly, these past approaches ignore the effect of physical drivers 101 in the crop system, which amplifies data heterogeneity as the same crop type 107 can develop very differently across space under different weather conditions.

Scientific models generally use system drivers to predict the response to these drivers when governed by entity characteristics of the system, in a process called forward modelling. For example, in the context of greenhouse gas emissions, drivers such as fossil fuel combustion, deforestation and industrial processes lead to the release of greenhouse gases, which further causes increased temperature and changes in precipitation. Given the system drivers, the observed responses can vary across different regions (entities) because they are also governed by entity characteristics such as the types of gas emitted and their lifetime in atmosphere. However, in some cases, these entity characteristics can be hard to estimate, which is where inverse modelling plays a role. Inverse modelling exists in multiple domains where the ‘hidden’ entity characteristics are estimated from the input drivers and observed responses. Inverse modelling, when applied to deep learning, involves training a deep learning framework to learn the inverse function of a forward process. The models discover hidden relationships between system parameters using driver-response data.

Embodiments described below use an inverse process for creating precise maps of a specific region of interest by uncovering the hidden relationship between physical drivers and satellite data in regard to crop growth. In particular, weather (driver)-satellite data (response) pairs are used to inversely infer the crop type (hidden entity characteristics), which is often difficult to precisely measure and requires extensive field surveys. This approach goes beyond traditional machine learning methods and offers new insights into understanding and predicting crop dynamics. In particular, we present WSTATT (Weather-based Spatio-Temporal segmentation networks with ATTention), a deep learning model that combines the spatio-temporal satellite and weather data with attention to give accurate pixel-wise crop-type segmentation maps for a given area. This model for crop mapping is superior to past satellite imagery-only based deep learning methods. We go on to show how the inverse modelling framework allows our attention module to better focus on the discriminative timeframes and thus lead to better predictions. We finally discuss the impact of inclusion of weather data in prediction for each crop class by correlating the results to their phenologies.

Our contributions can be summarized as follows:
We propose a system-based modeling strategy that incorporates crop-growth into deep learning models.
We, for the first time, develop a deep learning model that uses both spatio-temporal weather and satellite data for pixel-wise crop-type mapping.
We show how our inverse modeling-based approach is better than the traditional satellite-only based approach over various crop mapping tasks such as in-region prediction, cross-region prediction, cross-year prediction, and cross-year early prediction.
We show how we can generate accurate maps for future years well before the current standard, by correlating our results with crop phenologies

### Problem Setting

Crop mapping is a semantic segmentation task, where the aim is to assign class labels to sub-areas of a target region. During training, we have the following data sources:
Satellite image time-series S=[S^{l}, . . . , S^{Ts}], where each S^{t}∈ [symbol] ^{L}^{_{w}}^{×B}^{ₛ}^{×C}^{ₛ} is a satellite image having (Lₛ×Bₛ) sub-areas at time t with Cₛ multi-spectral channels. In many embodiments, each sub-area is represented by a single pixel in each image.
Weather time-series W=[W^{l}, . . . , W^{Tw}], where each W^{t}∈ [symbol] ^{L}^{_{w}}^{×B}^{_{w}}^{×C}^{_{w}} is temporal snap-shot of weather data for (L_{w}×B_{w}) sub-areas at time t with C_{w} channels each representing a different form of weather data such as daylight period, daily total precipitation, incident shortwave radiation flux density, snow water equivalent, maximum 2-meter air temperature, minimum 2-meter air temperature, average partial pressure of water vapor. Note that the temporal frequency of the satellite image time series and weather data need not be the same and that the size of the sub-areas need not be the same in the training data.
Labels Y∈{0,1}^{Ls×Bs×C} in one-hot representation, where C is the number of classes and labels are provided for each sub-area in the satellite images.

### Deep Learning model

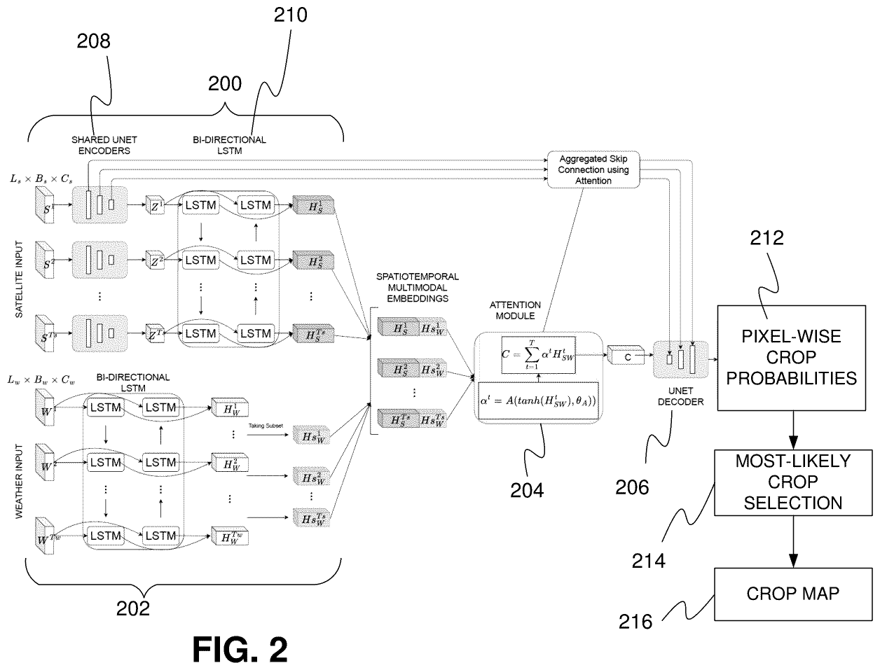

The present embodiments use an encoder-decoder setup with temporal attention to predict a pixel-wise segmentation map while incorporating weather data into an inverse framework. FIG. 2 provides a block diagram of the architecture of one embodiment. The architecture has two separate encoders: encoder 200 for the satellite data Eₛ(·; θ_{Es}) and encoder 202 for the weather data E_{q}(·; θ_{Eq}). This is followed by an attention module A(·; θ_{A}) 204, which uses both encoders' outputs. Finally, a decoder D(·; θ_{D}) 206 is used to create the maps.

The satellite data encoder Eₛ(·; θ_{Es}) consists of a convolutional layer 208 and a bidirectional LSTM layer 210 to capture spatial context and temporal dynamics, respectively. The convolutional layers encode each satellite image S^{t} to Z^{t}, and create a time series of spatial embeddings Z=[Z^{l}, . . . , Z^{Ts}], where each Z^{t} is a collection of Zᵢⱼ^{t} with a separate spatial embedding for each sub-area of the Lₛ×Bₛ sub-areas in the image. The parameters in the convolution layers are shared across multiple images in the input time series. To capture the temporal dependencies within the spatial embeddings, this series is passed into bidirectional LSTM 210 to get a time series of satellite/spectral hidden states H_{S}=H_{S}¹, . . . , H_{S}^{T} where each H_{S}^{t} is a collection of hidden states H_{S,i,j}^{t} with one hidden state for each sub-area of the Lₛ×Bₛ sub-areas in the image and each hidden state H_{S,i,j}^{t} is a concatenation of a forward LSTM spectral spatial hidden state H_{S,f,i,j}^{t} and a backward LSTM spectral spatial hidden state H_{S,b,i,j}^{t}. The forward LSTM is governed by the following set of equations, which use the previous hidden state H_{S,f,ij}^{t-1} and cell state C_{S,f,i,j}¹⁻¹ to generate the current hidden state H_{S,f,ij}^{t}:

$$\begin{matrix}{F}_{S , f , ij}^{t} = σ ( {Q}_{f , H}^{F} {H}_{S , f , ij}^{t - 1} + {Q}_{f , Z}^{F} {Z}_{ij}^{t} ) \\ {I}_{S , f , ij}^{t} = σ ( {Q}_{f , H}^{I} {H}_{S , f , ij}^{t - 1} + {Q}_{f , Z}^{I} {Z}_{ij}^{t} ) \\ {O}_{S , f , ij}^{t} = σ ( {Q}_{f , H}^{O} {H}_{S , f , ij}^{t - 1} + {Q}_{f , Z}^{O} {Z}_{ij}^{t} ) \\ {G}_{S , f , ij}^{t} = tan h ( {Q}_{f , H}^{G} {H}_{S , f , ij}^{t - 1} + {Q}_{f , Z}^{G} {Z}_{ij}^{t} ) \\ {C}_{S , f , ij}^{t} = {F}_{S , f , ij}^{t} ⊙ {C}_{S , f , ij}^{t - 1} + {I}_{S , f , ij}^{t} ⊙ {G}_{S , f , ij}^{t} \\ {H}_{S , f , ij}^{t} = {O}_{S , f , ij}^{t} ⊙ tan h ( {C}_{S , f , ij}^{t} )\end{matrix} \} i , j ∈ ( {L}_{s} {B}_{s} ) \qquad ( 1 )$$

The backward LSTM is governed by the following set of equations which use the next hidden state H_{S,b,ij}^{t+1} and cell state C_{S,b,ij}¹⁺¹ to generate the current hidden state H_{S,b,ij}^{t}:

$$\begin{matrix}{F}_{S , b , ij}^{t} = σ ( {Q}_{b , H}^{F} {H}_{S , b , ij}^{t + 1} + {Q}_{b , Z}^{F} {Z}_{ij}^{t} ) \\ {I}_{S , b , ij}^{t} = σ ( {Q}_{b , H}^{I} {H}_{S , b , ij}^{t + 1} + {Q}_{b , Z}^{I} {Z}_{ij}^{t} ) \\ {O}_{S , b , ij}^{t} = σ ( {Q}_{b , H}^{O} {H}_{S , b , ij}^{t + 1} + {Q}_{b , Z}^{O} {Z}_{ij}^{t} ) \\ {G}_{S , b , ij}^{t} = tan h ( {Q}_{b , H}^{G} {H}_{S , b , ij}^{t + 1} + {Q}_{b , Z}^{G} {Z}_{ij}^{t} ) \\ {C}_{S , b , ij}^{t} = {F}_{S , b , ij}^{t} ⊙ {C}_{S , b , ij}^{t + 1} + {I}_{S , b , ij}^{t} ⊙ {G}_{S , b , ij}^{t} \\ {H}_{S , b , ij}^{t} = {O}_{S , b , ij}^{t} ⊙ tan h ( {C}_{S , b , ij}^{t} )\end{matrix} \} i , j ∈ ( {L}_{s} {B}_{s} ) \qquad ( 2 )$$

where each Q represents a respective weight as indicated by the superscript and subscript notations.

A bidirectional LSTM is used because differentiating between two crop classes can be done only during a certain timeframe, called the discriminative period. To effectively capture this discriminative period, examining the forward and backward directions across the entire year is necessary.

Similarly, the weather data encoder consists of a bidirectional LSTM to encode the weather data into its respective time series of weather hidden states H_{W}=[H_{W}¹, . . . , H_{W}^{T}] where each H_{W}^{t} is a collection of hidden states H_{W,i,j}^{t} with one hidden state for each sub-area of the L_{w}×B_{w} sub-areas of the weather data and each hidden state H_{W,i,j}^{t} is a concatenation of a forward LSTM weather spatial hidden state H_{W,f,i,j}^{t} and a backward LSTM weather spatial hidden state H_{W,b,i,j}^{t}. The forward LSTM is governed by the following set of equations, which use the previous hidden state H_{W,f,ij}^{t-1} and cell state C_{W,f,ij}¹⁻¹ to generate the current hidden state H_{W,f,ij}^{t}:

$$\begin{matrix}{F}_{W , f , ij}^{t} = σ ( {Y}_{f , H}^{F} {H}_{W , f , ij}^{t - 1} + {Y}_{f , W}^{F} {W}_{ij}^{t} ) \\ {I}_{W , f , ij}^{t} = σ ( {Y}_{f , H}^{I} {H}_{W , f , ij}^{t - 1} + {Y}_{f , W}^{I} {W}_{ij}^{t} ) \\ {O}_{W , f , ij}^{t} = σ ( {Y}_{f , H}^{O} {H}_{W , f , ij}^{t - 1} + {Y}_{f , W}^{O} {W}_{ij}^{t} ) \\ {G}_{W , f , ij}^{t} = tan h ( {Y}_{f , H}^{G} {H}_{f , ij}^{t - 1} + {Y}_{f , W}^{G} {W}_{ij}^{t} ) \\ {C}_{W , f , ij}^{t} = {F}_{W , f , ij}^{t} ⊙ {C}_{W , f , ij}^{t - 1} + {I}_{W , f , ij}^{t} ⊙ {G}_{W , f , ij}^{t} \\ {H}_{W , f , ij}^{t} = {O}_{W , f , ij}^{t} ⊙ tan h ( {C}_{W , f , ij}^{t} )\end{matrix} \} i , j ∈ ( {L}_{w} {B}_{w} ) \qquad ( 3 )$$

The backward LSTM is governed by the following set of equations which use the next hidden state H_{W,b,ij}^{t-1} and cell state C_{W,b,ij}^{t+1} to generate the current hidden state H_{W,b,ij}^{t}:

$$\begin{matrix}{F}_{W , b , ij}^{t} = σ ( {Y}_{b , H}^{F} {H}_{W , b , ij}^{t + 1} + {Y}_{b , Z}^{F} {W}_{ij}^{t} ) \\ {I}_{W , b , ij}^{t} = σ ( {Y}_{b , H}^{I} {H}_{W , b , ij}^{t + 1} + {Y}_{b , Z}^{I} {W}_{ij}^{t} ) \\ {O}_{W , b , ij}^{t} = σ ( {Y}_{b , H}^{O} {H}_{W , b , ij}^{t + 1} + {Y}_{b , Z}^{O} {W}_{ij}^{t} ) \\ {G}_{W , b , ij}^{t} = tan h ( {Y}_{b , H}^{G} {H}_{W , b , ij}^{t + 1} + {Y}_{b , Z}^{G} {W}_{ij}^{t} ) \\ {C}_{W , b , ij}^{t} = {F}_{W , b , ij}^{t} ⊙ {C}_{W , b , ij}^{t + 1} + {I}_{W , b , ij}^{t} ⊙ {G}_{W , b , ij}^{t} \\ {H}_{W , b , ij}^{t} = {O}_{W , b , ij}^{t} ⊙ tan h ( {C}_{W , b , ij}^{t} )\end{matrix} \} i , j ∈ ( {L}_{w} {B}_{w} ) \qquad ( 4 )$$

where each Y represents a respective weight as indicated by the superscript and subscript notations.

Compared with satellite images, weather data are often collected at a higher temporal frequency (e.g., daily) but in a coarser spatial resolution. Instead of using convolutional layers, here we select the sub-area size for the weather data such that the weather drivers remain the same for all the image sub-areas (pixels in some embodiments) within a weather sub-area. Now the bidirectional LSTM encoder will result in a hidden state for each timestamp of the weather data, and this implies that the length of the weather embeddings list (H_{W}) is equal to the number of timestamps of weather data present. This makes H_{S} and H_{W} of unequal length as the temporal frequency of weather data is much higher than that of satellite data. To correct this, the hidden weather states are sampled at the rate of the image data. For example, if a new satellite image is received every 15 days and weather data is collected daily, every 15th weather data embedding is sampled producing Hs_{W}, which is the same length as H_{S}. Each weather hidden state is created using previous hidden states (Equation 3) and future hidden states (Equation 4), therefore all the weather data present is still used even though only select hidden states are being sampled. So even if, for example, the 15th day has noisy weather readings, since the 15th weather embedding is created using this noisy reading, all previous weather readings, and all future weather readings, it will still contain relevant information as the Bi-LSTM encoder would be able to capture the right information. Note that this embodiment uses temporally-based sampling as opposed to averaging to avoid losing dynamic changes in the weather that would be removed by averaging. After this equally temporally spaced selection of embeddings, we are left with a subset of weather data embeddings Hs_{W}=[Hs_{W}¹, . . . , Hs_{W}^{T}^{ₛ}], the same length as H_{S}.

Before applying the hidden states to the attention module, the number of hidden states for the image data and the weather data at each time t must match. For the image data, there are Lₛ×Bₛ hidden states H_{s,ij}^{t} and for the weather data, there are L_{w}×B_{w} hidden states H_{W,ij}^{t} at any time t. In accordance with one embodiment, Lₛ, Bₛ, L_{w}, and B_{w} are selected such that the boundaries of the larger sub-areas defined by L_{w} and B_{w} are each aligned with boundaries of the smaller sub-areas defined by Lₛ and Bₛ. As a result, each larger sub-area contains an integer number of smaller sub-areas. Now, to match the number of hidden states at each time t, each hidden state H_{W,ij}^{t} is repeated Lₛ×Bₛ/L_{w}×B_{w} times.

Now that the satellite embeddings list (H_{S}) and a subset of the weather embeddings list (Hs_{W}) are of the same spatial and temporal dimensions, we concatenate them along the channel dimension to create a time series of combined hidden states H_{SW}=[H_{SW}¹, . . . , H_{SW}^{T}^{ₛ}]. This series represents the spatiotemporal multimodal embeddings of both the satellite images and the weather data, thus enabling the inverse modeling approach by forcing all future components in the method to use both modalities jointly. This multimodal embedding series is then passed onto the attention network, which uses the series to assign a weight for each timestamp dynamically. The attention weight for each timestamp ranges in (0,1) and sums up to 1 over all the timestamps. The weight represents the importance of data at each timestamp towards the final goal of crop mapping. We used a single layer feed-forward network as the attention layer for our implementation. The attention network is included to better capture and give more importance to the discriminative period. This module helps the model focus on which embeddings are more important in the time series and can help eliminate issues such as cloud cover blockage or missing data. The series H_{SW} is aggregated temporally using these attention weights to form the final embedding series C_{SW}=[C_{SW}¹, . . . , C_{SW}^{T}].

This attention-aggregated series is then sent into the decoder. The decoder is a set of convolutional layers, similar to the UNET deconvolution approach. Since the input to the decoder is a multimodal attention aggregated series, it is forced to learn the relationship between these embeddings and the final crop map, which is the idea behind the inverse modeling paradigm. We also use aggregated skip connections using attention, using the attention weights at every step of the decoding. Finally, we use a linear layer followed by softmax to get the pixel-wise crop probabilities 212. The model can be trained using pixel-wise cross-entropy loss.

The pixel-wise crop probabilities 212 provide a probability for each possible crop at each pixel of the image. In accordance with one embodiment, the crop with the highest probability is selected as the crop for the pixel by a most-likely crop selection 214. In other words, crop selection 214 identifies and provides a land cover type for each sub-area represented by an image pixel. The crops for the image pixels are then used to form a crop map 216 that indicates the crop of each sub-area covered by an image pixel. In some embodiments, crop map 216 is a generated image that uses different colors to depict different crops in the area covered by the image. In other embodiments, crop map 216 is a textual description of the locations of different crops. In accordance with some embodiments, the crop identified for a pixel is used directly in crop map 216. In other embodiments, a smoothing step is used to reduce noisy crop designations.

### Dataset and Implementation Details

### Region of Analysis

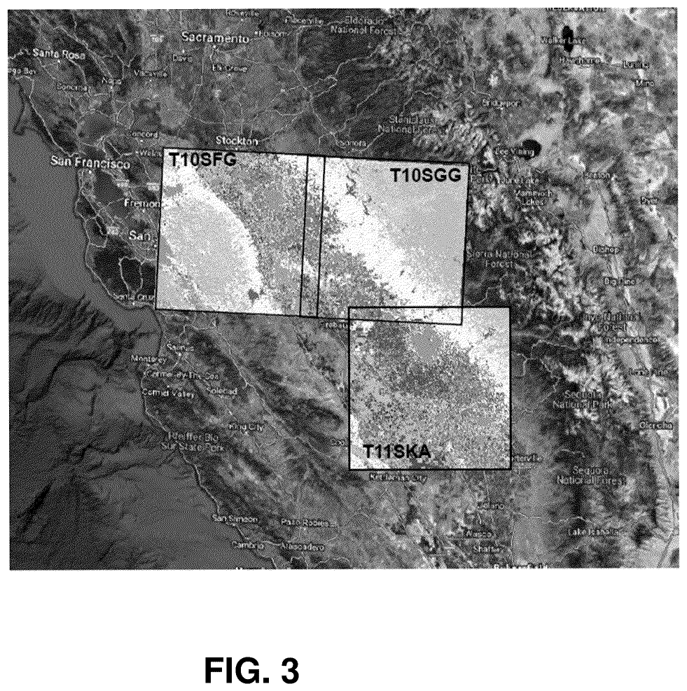

For testing, the regions demarcated by the T11SKA, T10SFG, and T10SGG Sentinel-2 Tiles, areas rich in crop cover with over 30 classes, was selected. A visualization of the location of all these tiles can be seen in FIG. 3. The labels for these Sentinel-2 Tiles are taken from the USDA Crop Data Layer and for training and testing are considered to be the ground truths for the crop covers.

### Satellite Imagery

Satellite imagery for training and testing was acquired from Google Earth Engine, and included multi-spectral images from the Sentinel-2 Constellation for the year 2018 from the COPERNI-CUS/S2 2 collection on Google Earth Engine. The Sentinel-2 data product has 13 spectral bands at different spatial resolutions of 10, 20, and 60 meters. The atmospheric bands (Band 1, 9, and 10) of 60 meters resolution were left out while all the remaining bands were resampled to 10 meters using the nearest neighbor method. Due to the unequally spaced temporal frequency of Sentinel-2 across years, a multi-spectral mosaic is created using all multi-spectral bands in a 15-day gap, considering cloud filters at every timestamp. Following this process, 24 mosaics from January to December of 2018 are produced. Each mosaic is of height and width (10980 pixels, 10980 pixels) and has ten channels, making each mosaic of size (10,10980,10980) with a spatial resolution of 10 meters square per pixel. Together, the 24 mosaics provide a data set containing (24×10×10980×10980) values per tile. One can obtain similar mosaic sets for each year, such as 2019 or 2020. These mosaic sets are obtained for each of the other Sentinel-2 Tiles: T11SKA, T10SGG and T10SFG.

### Weather Data

In accordance with one embodiment, weather data was obtained from Daymet via the Google Earth Engine, specifically from the NASA/ORNL/DAYMET V4 3 collection on Google Earth Engine. The Daymet product has seven bands: Duration of the daylight period, Daily total precipitation, Incident shortwave radiation flux density, Snow water equivalent, maximum 2-meter air temperature, minimum 2-meter air temperature, average partial pressure of water vapor. The data has a resolution of 1000 meters and has a daily temporal frequency. However, we found that downloading the data at a resolution of 1000 meters led to a lot of missing data, so we download all bands of data daily at a resolution of 10000 meters for all areas of interest (AOIs), i.e., T11SKA, T10SGG and T10SFG. We then resample the height and width to a spatial extent of 10980 each, using the nearest neighbor, to match the spatial extent with that of Sentinel-2 and normalise each band with its respective minimums and maximums. This results in a daily array of shapes (7,10,10), i.e., seven bands of weather data at a spatial resolution of 10980 meters each day. So the final shape of the weather data is (365,7,10,10) for each Sentinel-2 Tile for each year.

### Labels

We get our labels from the Cropland Data Layer (CDL) provided by the United States Department of Agriculture (USDA). The United States Department of Agriculture (USDA) annually releases the Cropland Data Layer (CDL), which provides a publicly available land-cover classification map for the entire country at a 30-meter resolution that includes major and minor crop commodities. We clip the data to our AOI; however, CDL is at a 30-meter resolution instead of our 10m prediction resolution. We resample the clipped CDL map to a 10-meter resolution using the nearest neighbor to solve this. There are over 200 class types in CDL, all of which are not present in the California region, and some are irrelevant to our crop mapping purpose. To reduce the size of the model, only 33 classes are used, namely Corn, Cotton, Rice, Sunflower, Barley, Winter Wheat, Safflower, Dry Beans, Onions, Tomatoes, Cherries, Grapes, Citrus, Almonds, Walnut, Pistachio, Garlic, Olives, Pomegranates, Alfalfa, Hay, Barren, Fallow and Idle, Deciduous Forests, Evergreen forest, Mixed Forests, Clover and wildflower, Shrubland, Grass, Woody wetlands, Herbaceous Wetlands, Water, Urban. We also have an Unknown class to denote those pixels that do not lie in the abovementioned categories. Therefore, for a given Sentinel-2 Tile, the final labels are of shape (34,10980,10980) for each year.

### Implementation Details

Looking at the entire region of T11SKA, not all areas are useful for crop mapping, such as cities or grasslands. To address this, one embodiment utlilizes grid-based splitting of the region. Specifically, each tile is separated into 10×10 grids, each of spatial extent 10980 m by 10980 m or 1098×1098 Sentinel-2 pixels. Grids that do not have enough crop cover in them (we implement a threshold that the grid should have at least 50% should be crop) are eliminated from the data. It is also known that CDL has issues with noise and incorrect labels at boundaries. To counter this, we perform one level of erosion and remove small connected components of the same class to reduce the effect of these incorrect labels in the training process.

Since we follow a grid-wise scheme for the satellite data, we also split the weather data into this grid scheme. This results in one weather reading for each grid, which is a decent approximation, as it can be expected that a region of 10 km² has the same weather.

### Experimental Results

The present embodiments were tested against a satellite-only based approach, referred to as STATT, which does not utilize weather data.

There are a variety of experiments related to pixel-wise crop mapping one can perform with full-year data, such as in-region prediction (Same Tile, Same Year), cross-region prediction (Different Tile, Same Year), and cross-year prediction (Same Tile, Different Year). One can also perform Early Prediction (Early Prediction on Different Years) with partial year data.

Training Set: We keep the training and validation sets across the experiments the same. We chose the training set to be 34 grids in T11SKA in 2018 and the validation set to be 14 different grids in T11SKA also in 2018. Both the present embodiment (WSTATT) and the prior art (STATT) were trained using these 34 grids, and the best model was chosen using the 14 validation grids in 2018. Both models were trained using the same settings (learning rate=0.0001 and 50 epochs) and a cross-entropy loss. Training was done using Nvidia V100 GPU.

### Predictive Performance: Full Year Data

Over the next few paragraphs, we discuss the predictive performance of experiments where both STATT and WSTATT use the full year's data.

Same Tile Same Year: In this experiment, the training set is a certain region in a particular tile, and the test set is a different region within that tile but the same year. Here the test set is 17 grids in T11SKA in 2018 that do not lie in either the training or the validation set. The F1 scores for both models on classes for which there were at least 100,000 pixels in the test set are shown in the first two columns of Table I under the column name ‘T11SKA 2018’, representing the test set used. We can see that WSTATT performs better than STATT in most crop classes, with a major difference in Corn. This experiment shows that within the same region and same year, the weather-based inverse model is better, but the benefits are limited to a few classes.

Different Tile Same Year: In this experiment, the training set is a certain region in a particular tile, but the test set are regions in a different tile but in the same year. Testing in a different tile compared to the training tile implies that there would be different weather and crops grown with their patterns changing in this new region. For this experiment, there are two test sets: i) 28 grids from the adjacent Sentinel-2 Tile of T10SGG in 2018 and ii) 46 grids from the Sentinel-2 Tile of T10SFG in 2018, which lies farther away from T11SKA compared to T10SGG. Since only grids from T11SKA were used in training, all grids in these two tiles can be used for testing. The grids chosen in these two test tiles do not overlap with any region in T11SKA. The F1 scores for both models on these test sets can be seen in Table I under the column names ‘T10SGG 2018’ and ‘T10SFG 2018’. We use a threshold of 100,000 test pixels per class per tile to be considered for evaluation, and those classes that do not cross the threshold are left blank with ‘-’. Since we are moving across tiles, the crops planted are affected due to different soil conditions, weather, and practices. Despite these challenges, WSTATT performs better than STATT in almost all classes, with major improvements in Alfalfa, Almonds, and Pistachio. This shows that WSTATT is more robust to cross-region prediction, which can be attributed to the fact that WSTATT uses weather data in its prediction process.

Same Tile Different Year: In this experiment, the training set is a certain region in a particular tile, but the test set is regions in the same tile but in a different year. A different year for testing implies very different weather, and the crops grown will shift for each pixel. However, due to different weather, the response time of crop growth would be different. Thus the hypothesis is that a model with weather input could capture this response. For this experiment as well, there are two test sets: i) 67 grids from T11SKA in 2019 and ii) 64 grids from T11SKA in 2020. Since only grids from 2018 are used in training, all grids from 2019 and 2020 can be used in testing. These test years would have a completely different weather pattern compared to the training year, thus making this experiment a good test to see the impact of weather. The F1 scores for both models on this test set can be seen in Table I under the columns ‘T11SKA 2019’ and ‘T11SKA 2020’. Once again, we use a threshold of 100,000 pixels in test set to be considered in the analysis. We can see from the table that the weather-based model can do much better than the satellite-only based method across years. Almost every class has a major improvement, showing that the weather based model can account for the weather shift across the year and accurately predict crop cover.

TABLE I
COMPARISON OF WSTATT AND STATT IN TERMS F1 SCORE OVER VARIOUS EXPERIMENTS.
THE NUMBERS IN BOLD CORRESPOND TO THE BEST ACROSS EACH EXPERIMENT

| | Same Year Same Tile | | Same Year Different Tile | | | | Same Tile Different Year | | | |
|---|---|---|---|---|---|---|---|---|---|---|
| | Test Set | | | | | | | | | |
| | T11SKA 2018 | | T10SGG 2018 | | T10SFG 2018 | | T11SKA 2019 | | T11SKA 2020 | |
| Class | STATT | WSTATT | STATT | WSTATT | STATT | WSTATT | STATT | WSTATT | STATT | WSTATT |
| Corn | 0.718 | 0.8014 | — | — | 0.1355 | 0.0634 | 0.7235 | 0.7575 | 0.7242 | 0.7779 |
| Cotton | 0.958 | 0.9583 | 0.1753 | 0.306 | 0.4079 | 0.5079 | 0.8242 | 0.8649 | 0.8330 | 0.8330 |
| Winter Wheat | 0.7276 | 0.7135 | 0.3818 | 0.5048 | 0.3311 | 0.5575 | 0.2675 | 0.3364 | 0.3904 | 0.4044 |
| Tomatoes | 0.8727 | 0.8921 | 0.0904 | 0.3003 | 0.1627 | 0.2432 | 0.7517 | 0.8194 | 0.7457 | 0.8420 |
| Grapes | 0.8691 | 0.8682 | 0.2619 | 0.3761 | 0.1785 | 0.2693 | 0.6474 | 0.7747 | 0.6984 | 0.7378 |
| Citrus | 0.7842 | 0.8007 | 0.7367 | 0.7982 | — | — | 0.8057 | 0.8363 | 0.6817 | 0.8127 |
| Almonds | 0.8197 | 0.8435 | 0.2625 | 0.6935 | 0.3674 | 0.6687 | 0.4216 | 0.7930 | 0.5383 | 0.7464 |
| Walnut | 0.8164 | 0.8537 | 0.1643 | 0.0612 | 0.4829 | 0.3628 | 0.6661 | 0.6938 | 0.5860 | 0.5792 |
| Pistachio | 0.8447 | 0.8778 | 0.2104 | 0.4775 | — | — | 0.4390 | 0.6773 | 0.3189 | 0.5057 |
| Alfalfa | 0.7605 | 0.7892 | 0.6589 | 0.7737 | 0.683 | 0.6418 | 0.6085 | 0.7942 | 0.6956 | 0.8346 |

### Early Predictive Performance: Partial Year Data

In this task, the training set is a certain region in a particular tile, but the test set is regions in the same tile but only part of the data in a different year. For example, training is done on data from 2018, but testing is done using only the first eight months of data from 2019. An accurate early prediction would be possible only if the model can identify crop growth differences within the provided data timeframe. Providing weather data would help in earlier classification with more confidence.

Both STATT and WSTATT have attention modules allowing dynamic timestamp weight allocation followed by aggregation. Hence, even if the full year's data is not provided, the attention module can assign weights to whatever timestamps are present and carry forward with aggregation and eventually map prediction. This feature allows for early prediction in various time scales. In other words, we can get a prediction map with eight months of data or just six months of data.

There are two test sets i) 67 grids from T11SKA in 2019 and ii) 64 grids from T11SKA in 2020. Now in both test sets, we vary the amount of data provided for prediction as six months, eight months, ten months, and 12 months, each starting from January. Thus, each year will have four sets of F1 scores, with each experiment increasing the amount of data provided. The results for these experiments can be seen in Table II, with the top half showing the F1 score comparison of both models in 2019 over the multiple time scales and the bottom half showing the counterpart 2020 experiment results. Here we can see a major difference and the weather-based model's importance. With just eight months of data in the test set over both years, we can see a consistent superiority of the weather-based model in all classes with astronomical differences in Cotton, Almonds, Pistachio, and Walnuts. This extends into the ten monthly predictions for 2020, but a few classes drop for 2019, but only by a little. Another important factor to note is that, though both model scores improve with more data, WSTATT reaches a better score much faster. For example, from the Cotton scores in 2019, we observe that with just eight months of data, WSTATT can achieve good accuracy, and with four more months of data, the score increases by 0.1. However, in the same timeframe, STATT's eight-month score is poor and shows a good value only when the full year's data is provided. This indicates that the weather model can use the weather data to make earlier predictions and effectively uses the partial year's data.

TABLE II
COMPARISON OF WSTATT AND STATT IN TERMS F1 SCORE OVER
VARIOUS EARLY PREDICTION SETTINGS. THE NUMBERS IN
BOLD CORRESPOND TO THE BEST ACROSS EACH EXPERIMENT.

| | Data Provided | | | | | | | |
|---|---|---|---|---|---|---|---|---|
| | 6 MONTHS | | 8 MONTHS | | 10 MONTHS | | 12 MONTHS | |
| Crop Class | STATT | WSTATT | STATT | WSTATT | STATT | WSTATT | STATT | WSTATT |

T11SKA 2019 Early Prediction

| | | | | | | | | |
|---|---|---|---|---|---|---|---|---|
| Corn | 0.3814 | 0.1424 | 0.5624 | 0.7279 | 0.6948 | 0.7688 | 0.7235 | 0.7575 |
| Cotton | 0.0080 | 0.4796 | 0.2287 | 0.7644 | 0.6898 | 0.8498 | 0.8242 | 0.8649 |
| Winter Wheat | 0.1385 | 0.3251 | 0.2570 | 0.3234 | 0.2818 | 0.3218 | 0.2675 | 0.3364 |
| Tomatoes | 0.1413 | 0.3814 | 0.6147 | 0.7936 | 0.7266 | 0.8186 | 0.7517 | 0.8194 |
| Grapes | 0.0159 | 0.2608 | 0.0881 | 0.5587 | 0.3855 | 0.6719 | 0.6474 | 0.7747 |
| Citrus | 0.5331 | 0.7571 | 0.6277 | 0.7663 | 0.7391 | 0.8059 | 0.8057 | 0.8363 |
| Almonds | 0.1110 | 0.3035 | 0.2441 | 0.7341 | 0.3060 | 0.7754 | 0.4216 | 0.7930 |
| Walnut | 0.3138 | 0.3166 | 0.3735 | 0.7032 | 0.4761 | 0.7503 | 0.6661 | 0.6938 |
| Pistachio | 0.0008 | 0.1002 | 0.0062 | 0.3567 | 0.0274 | 0.3765 | 0.4390 | 0.6773 |
| Alfalfa | 0.4025 | 0.7046 | 0.5034 | 0.7586 | 0.5681 | 0.7899 | 0.6085 | 0.7942 |

T11SKA 202 0 Early Prediction

| | | | | | | | | |
|---|---|---|---|---|---|---|---|---|
| Corn | 0.6402 | 0.3591 | 0.7063 | 0.7231 | 0.7543 | 0.7948 | 0.7242 | 0.7779 |
| Cotton | 0.1135 | 0.4112 | 0.2579 | 0.7444 | 0.4736 | 0.8163 | 0.8330 | 0.8330 |
| Winter Wheat | 0.3896 | 0.4479 | 0.4433 | 0.4529 | 0.3934 | 0.4267 | 0.3904 | 0.4044 |
| Tomatoes | 0.3863 | 0.3244 | 0.5872 | 0.7929 | 0.6825 | 0.8355 | 0.7457 | 0.8420 |
| Grapes | 0.0604 | 0.1837 | 0.2583 | 0.4391 | 0.5538 | 0.6527 | 0.6984 | 0.7378 |
| Citrus | 0.6098 | 0.7410 | 0.6493 | 0.7611 | 0.5893 | 0.8143 | 0.6817 | 0.8127 |
| Almonds | 0.3749 | 0.6868 | 0.4091 | 0.7250 | 0.4050 | 0.7374 | 0.5383 | 0.7464 |
| Walnut | 0.4989 | 0.6467 | 0.4489 | 0.7635 | 0.3092 | 0.6960 | 0.5860 | 0.5792 |
| Pistachio | 0.0003 | 0.2620 | 0.0040 | 0.3173 | 0.0368 | 0.3489 | 0.3189 | 0.5057 |
| Alfalfa | 0.5092 | 0.7884 | 0.6057 | 0.7980 | 0.6233 | 0.8336 | 0.6956 | 0.8346 |

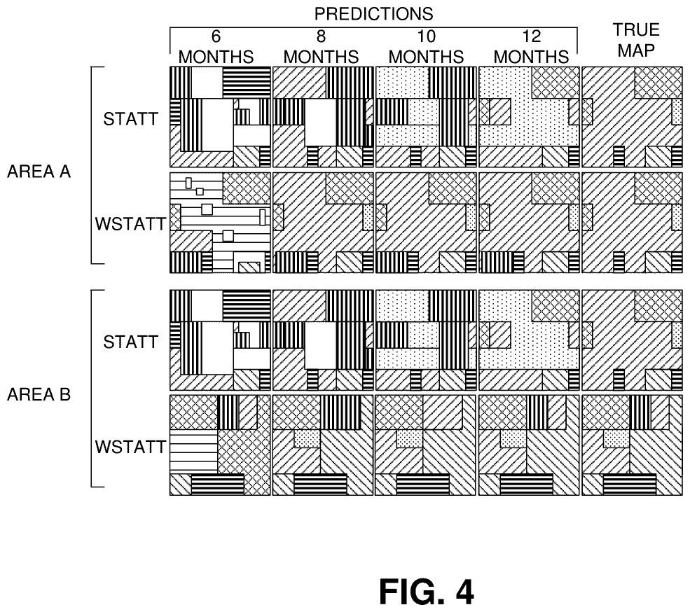

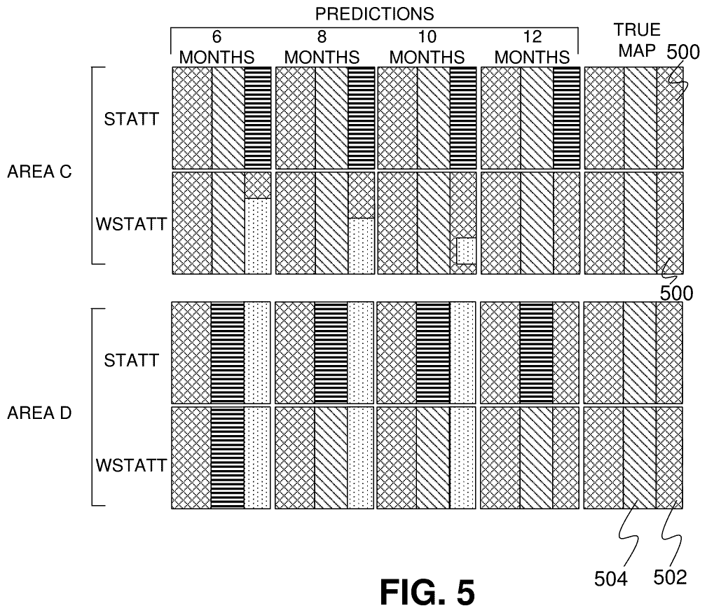

To support our observation, we present prediction maps for certain regions in FIGS. 4 and 5. FIG. 4 illustrates two cases (Area A and Area B) where the prediction by WSTATT using only eight months of data (shown in the second column) is close to the ground truth of CDL (shown in the last column). Although some corrections are made with more data, the majority of the patch is captured within eight months. However, with the same amount of data at eight months, STATT cannot provide a good prediction. In fact, even with more data provided, STATT is unable to reach a good prediction in these patches. FIG. 5 shows two areas (Area C and Area D) where the weather model can correct some fields as more data is provided, but STATT is unable to do so. In Area C of FIG. 5, WSTATT has some errors in a field 500 at the six month prediction but improves and eventually becomes perfect by the end of the year. However, STATT cannot correct itself and predicts the wrong crop for field 500, even with the full year's data. Similarly, in area D, WSTATT corrects two fields, 504 and 502, as more data is given, with field 504 being corrected faster when compared to field 502. In that same time frame, STATT is only able to reach a correct prediction for field 502 with the full year's data, but not for field 504 despite having full data.

Through our experiment, we have found that the weather-based model can adjust to different seasons and produce accurate maps well before the end of the year, reaching even higher accuracy by the end of the year. This is a significant advancement in crop mapping since the CDL map for a given year is usually provided a month after the year ends, which would be around late January or early February for the 2020 map. Our method can provide the map as early as five months in advance, which can greatly improve crop management, pest control, and yield predictions.

### Attention Analysis

The previous sections show that the weather-based model outperforms the satellite-only approach in different tasks. The reason behind this is the integration of the inverse modeling scheme that enhances prediction accuracy. Additionally, we examine the attention module of both approaches to determine if incorporating weather improves other parts of the model.

Both approaches utilize a feed-forward attention module that assigns a weight to each timestamp. However, the method of assigning this weight differs between STATT and WSTATT. STATT solely uses satellite data embeddings, while WSTATT utilizes both satellite and weather data embeddings to make the decision. Therefore, when analyzing the same patch, does the inclusion of weather data affect the attention given to each timestamp?

For the STATT model to make accurate use of training data, it must consider various factors. These include phenology-related features, which are generalizable, and other patterns like crop residues and backgrounds that correlate with crop labels in the training set. However, STATT doesn't consider the natural timeline and only captures sequence dependencies. Thus, it must pay attention to timestamps with these artificial factors for accuracy. The model may perform poorly in different regions or years where these factors aren't present.

The WSTATT model combines weather and image embeddings to better understand weather conditions and important periods for identifying crops. With an improved attention structure, the model is able to focus on key periods by referencing a combination of weather and image data. This leads to simpler, more accurate patterns and better performance without overfitting to false patterns. The resulting attention curve is sharper and the extracted patterns are more related to true phenology, making them more applicable to testing data. To confirm this, we examine the attention weights assigned to the same patch by both methods in areas where the patch is mostly composed of a single class. This analysis helps us determine if the predicted attention weights are located within the appropriate distinguishing periods for that crop class.

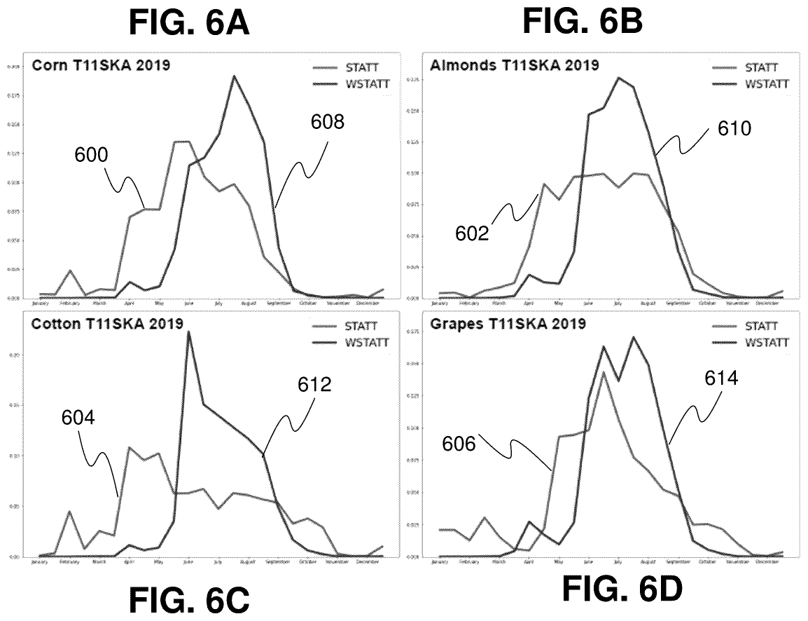

In 2019, we examined several patches for different classes within the T11SKA tile located in a test region. FIGS. 6A, 6B, 6C and 6D show the attention weights for corn, almonds, cotton and grapes over a growing season. Graphs 600, 602, 604 and 606 show the attention weights of STATT and graphs 608, 610, 612, and 614 show the attention weights of WSTATT. The x-axis of each graph represents the timeframe and the y-axis shows the weightage for the corresponding timestamp. The analysis revealed that WSTATT provided a sharper attention curve during the crop growth period in the middle of the year. For instance, WSTATT focused on June to September for almonds, which was the easiest period to distinguish them from other crops. In contrast, STATT attention scores were almost equal from April to September. Similarly, for Corn, STATT focused on the period from April to July, which could cause confusion with winter wheat, while WSTATT paid attention to July to September. It is important to note that WSTATT was provided with weather data, which helped make better predictions and identify the right time frames to focus on.

### Discussion on Impact of Weather

In the previous sections, we saw that combining weather data and satellite imagery for crop mapping improves predictive accuracy through multiple experiments. This section explores how crop phenology impacts the results presented in Tables I and II and evaluates the influence of weather on crop growth. Certain variables change when transitioning to a different year or Sentinel-2 tile, affecting crop growth and its phenological stages. As a result, aspects like planting and harvest times and leaf shedding can vary across other regions and years. Temperature, one of the weather elements we analyze, plays a crucial role in determining the timing of leaf shedding, while the amount of daylight received throughout the year can help determine when the crop has matured. In our deep-learning approach, we also use satellite imagery to capture crop greenness and biomass. By examining Tables I and II, we can compare the classification performance of different methods in capturing these aspects for each crop.

Corn is usually planted in May, but its leaf area index is still low after six months, making it difficult to classify accurately. Winter wheat is almost at the end of its growth cycle, and some fields may have residue, which can confuse with corn. However, since winter wheat's growth cycle is complete, Table II shows that its predictive performance does not improve significantly beyond the six-month prediction, regardless of the data provided for both methods over the years. Tomatoes have different planting times but are harvested between July and October. Therefore, their predictive performance shows a significant increase at eight months compared to six months for WSTATT but not as much for STATT. Similarly, Cotton is typically planted in April, but it reaches good vegetative cover later in the year, resulting in a sharp increase in predictive performance for WSTATT but not for STATT.

Grapes, a perennial crop, are harvested in September or October and shed their leaves during winter. WSTATT is quicker than STATT in detecting this, with a notable increase in performance for the 6 to 8 months prediction for WSTATT as opposed to 8 to 10-month prediction for STATT. Almonds, pistachios, and walnuts are also perennial crops, but they shed their leaves later in the year, around October to December, causing a jump in their performance around the eight months timestamp. Pistachio, being the last to shed its leaves, shows a boost in performance only on the last timestamp. In contrast, citrus and alfalfa maintain their leaves throughout the year, providing good predictive performance even from 6 months onwards. Additionally, Table I shows that these two crops perform well across tiles, as they have leaves throughout the year in any region.

The results indicate that including weather data is useful for identifying harvest periods more quickly and accurately capturing intervals of leaf loss. Weather data is updated more frequently than satellite data, allowing WSTATT to detect dependencies sooner. The attention analysis section further demonstrated the accuracy of interval capture.

The embodiments provide a new method for crop mapping that considers crop growth as a system influenced by physical drivers such as weather and soil type. The embodiments provide an inverse modeling approach using satellite imagery and weather data that provides accurate pixel-wise crop cover for a given area of interest. The weather-based method outperforms traditional satellite-only methods for tasks such as in-year prediction, cross-region prediction, cross-year prediction, and cross-year early prediction. The early prediction ability of the embodiments allows for more accurate and timely crop maps to be available to farmers and the public much sooner than the current standard (up to 5 months in advance).

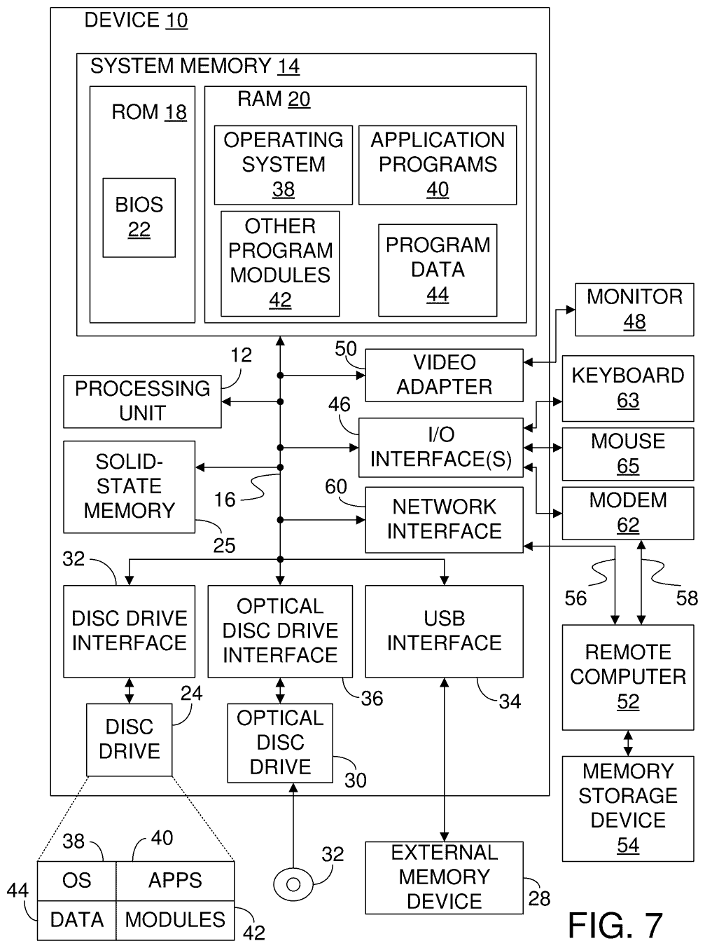

FIG. 7 provides an example of a computing device 10 that can be used to implement the encoders, attention module and decoder shown in FIG. 2. Computing device 10 includes a processing unit 12, a system memory 14 and a system bus 16 that couples the system memory 14 to the processing unit 12. System memory 14 includes read only memory (ROM) 18 and random-access memory (RAM) 20. A basic input/output system 22 (BIOS), containing the basic routines that help to transfer information between elements within the computing device 10, is stored in ROM 18. Computer-executable instructions that are to be executed by processing unit 12 may be stored in random access memory 20 before being executed.

Computing device 10 further includes an optional hard disc drive 24, an optional external memory device 28, and an optional optical disc drive 30. External memory device 28 can include an external disc drive or solid-state memory that may be attached to computing device 10 through an interface such as Universal Serial Bus interface 34, which is connected to system bus 16. Optical disc drive 30 can illustratively be utilized for reading data from (or writing data to) optical media, such as a CD-ROM disc 32. Hard disc drive 24 and optical disc drive 30 are connected to the system bus 16 by a hard disc drive interface 32 and an optical disc drive interface 36, respectively. The drives and external memory devices and their associated computer-readable media provide nonvolatile storage media for the computing device 10 on which computer-executable instructions and computer-readable data structures may be stored. Other types of media that are readable by a computer may also be used in the exemplary operation environment.

A number of program modules may be stored in the drives and RAM 20, including an operating system 38, one or more application programs 40, other program modules 42 and program data 44. In particular, application programs 40 can include programs for implementing the encoders, attention module and decoder discussed above. Program data 44 may include any data used by the systems and methods discussed above.

Processing unit 12, also referred to as a processor, executes programs in system memory 14 and solid-state memory 25 to perform the methods described above.

Input devices including a keyboard 63 and a mouse 65 are optionally connected to system bus 16 through an Input/Output interface 46 that is coupled to system bus 16. Monitor or display 48 is connected to the system bus 16 through a video adapter 50 and provides graphical images to users. Other peripheral output devices (e.g., speakers or printers) could also be included but have not been illustrated. In accordance with some embodiments, monitor 48 comprises a touch screen that both displays input and provides locations on the screen where the user is contacting the screen.

The computing device 10 may operate in a network environment utilizing connections to one or more remote computers, such as a remote computer 52. The remote computer 52 may be a server, a router, a peer device, or other common network node. Remote computer 52 may include many or all of the features and elements described in relation to computing device 10, although only a memory storage device 54 has been illustrated in FIG. 7. The network connections depicted in FIG. 7 include a local area network (LAN) 56 and a wide area network (WAN) 58. Such network environments are commonplace in the art.

The computing device 10 is connected to the LAN 56 through a network interface 60. The computing device 10 is also connected to WAN 58 and includes a modem 62 for establishing communications over the WAN 58. The modem 62, which may be internal or external, is connected to the system bus 16 via the I/O interface 46.

In a networked environment, program modules depicted relative to the computing device 10, or portions thereof, may be stored in the remote memory storage device 54. For example, application programs may be stored utilizing memory storage device 54. In addition, data associated with an application program may illustratively be stored within memory storage device 54. It will be appreciated that the network connections shown in FIG. 7 are exemplary and other means for establishing a communications link between the computers, such as a wireless interface communications link, may be used.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms for implementing the claims.

What is claimed is:

1. A method comprising:
receiving spatiotemporal spectral information for an area, wherein the area is divided into sub-areas and the spatiotemporal spectral information comprises spectral values for each sub-area;
receiving spatiotemporal weather information for the area;
forming spatiotemporal hidden states from the spatiotemporal spectral information and the spatiotemporal weather information;
applying the spatiotemporal hidden states to a neural network to obtain a land cover type for each sub-area of the area.

2. The method of claim 1 wherein forming the spatiotemporal hidden states comprises:
forming a time series of spectral spatial hidden states from the spatiotemporal spectral information;
forming a time series of weather spatial hidden states from the spatiotemporal weather information; and
at each time point in the time series of spectral spatial hidden states, concatenating a spectral spatial hidden state with a respective weather spatial hidden state.

3. The method of claim 2 wherein forming the time series of spectral spatial hidden states comprises utilizing a bidirectional long short term memory to produce the time series of spectral spatial hidden states.

4. The method of claim 3 wherein forming the time series of weather spatial hidden states comprises utilizing a bidirectional long short term memory to produce the time series of weather spatial hidden states.

5. The method of claim 2 wherein the spatiotemporal spectral information has a first frequency and the spatiotemporal weather information has a second frequency, wherein the second frequency is greater than the first frequency.

6. The method of claim 5 wherein forming the time series of weather spatial hidden states comprises forming a first time series of weather spatial hidden states having the second frequency and sampling the first time series of weather spatial hidden states to form a second time series of weather spatial hidden states having the first frequency.

7. The method of claim 2 wherein forming a time series of weather spatial hidden states comprises forming a first time series of weather spatial hidden states at a first spatial resolution and converting the first time series of weather spatial hidden states to a second time series of weather spatial hidden states at a second spatial resolution.

8. A system for predicting land cover types for sub-areas in an area, the system comprising:
an encoder:
receiving a time series of spectral values for each sub-area in the area;
receiving a time series of weather values for the sub-areas in the area;
using the time series of spectral values to determine a time series of hidden spectral states;
using the time series of weather values to determine a time series of hidden weather states;
combining the time series of hidden spectral states and the time series of hidden weather states to form a time series of combined hidden states;
an attention neural network:
aggregating the combined hidden states to form final embedding hidden states while providing different levels of attention to different respective time points in the time series of combined hidden states;
a decoder:
providing probabilities for each of a plurality of land cover types for each sub-area based on the final embedding states; and
a selector:
using the probabilities for each of the plurality of land cover types for each sub-area to select a land cover type for each sub-area.

9. The system of claim 8 wherein the time series of spectral values is a lower frequency than the time series of weather values.

10. The system of claim 8 wherein using the time series of spectral values to determine the time series of hidden spectral states comprises using a bidirectional long short term memory.

11. The system of claim 10 wherein the time series of hidden spectral states comprises a time series of forward hidden spectral states and a time series of backward hidden spectral states.

12. The system of claim 10 wherein using the time series of spectral values to determine the time series of hidden weather states comprises using a bidirectional long short term memory.

13. The system of claim 12 wherein the time series of hidden weather states comprises a time series of forward hidden weather states and a time series of backward hidden weather states.

14. The system of claim 8 wherein the time series of spectral values and the time series of weather values span less than a year.

15. A method comprising:
generating hidden states from a combination of spectral data and weather data for an area comprising a plurality of sub-areas;
applying the hidden states to an attention neural network to form an embedding;
applying the embedding to a decoder to generate probabilities for a plurality of possible land covers for each sub-area; and
using the probabilities to identify a land cover for each sub-area.

16. The method of claim 15 wherein generating hidden state from a combination of spectral data and weather data comprises:
receiving a time series of spectral data for the area;
using bidirectional long short term memory to generate spectral hidden states;
receiving a time series of weather data for the area;
using bidirectional long short term memory to generate weather hidden states; and
combining the spectral hidden states and the weather hidden states to form the hidden states.

17. The method of claim 16 wherein using bidirectional long short term memory to generate the spectral hidden states comprises forming a forward time series of spectral hidden states and a backward time series of spectral hidden states.

18. The method of claim 17 wherein using bidirectional long short term memory to generate the weather hidden states comprises forming a forward time series of weather hidden states and a backward time series of weather hidden states.

19. The method of claim 16 wherein the time series of spectral data for the area spans less than a year.

20. The method of claim 16 wherein a frequency of the time series of spectral data is less than a frequency of the time series of weather data.
